(19) United States
(12) Patent Application Publication
(10) Pub. No.: US 2016/0370428 A1
(43) Pub. Date: Dec. 22, 2016

(54) PORTABLE TEST APPARATUS FOR A SEMICONDUCTOR APPARATUS, AND TEST METHOD USING THE SAME

(71) Applicant: SK hynix Inc., Icheon-si Gyeonggi-do (KR)

(72) Inventor: Geun Ho CHOI, Icheon-si Gyeonggi-do (KR)

(21) Appl. No.: 14/845,010

(22) Filed: Sep. 3, 2015

(30) Foreign Application Priority Data
Jun. 17, 2015 (KR) 10-2015-0085725

(51) Int. Cl. G01R 31/317; G01R 31/3177

(52) U.S. Cl. CPC G01R 31/31703; G01R 31/3177

(57) ABSTRACT

A portable test apparatus may be provided. The portable test apparatus may include a socket board configured to allow mounting of a semiconductor apparatus decapsulated for package testing. The portable test apparatus may include a test logic board electrically coupled to the socket board, the test logic board configured to perform a test on the semiconductor apparatus and for analyzing a test result. The test logic board may receive power through the socket board. The test logic board may be configured for receiving a command from outside the test apparatus, generating and analyzing a test pattern, and outputting the test result.

### CROSS-REFERENCES TO RELATED APPLICATION

This application claims priority under 35 U.S.C. 119(a) to Korean application No. 10-2015-0085725, filed on Jun. 17, 2015, in the Korean intellectual property Office, which is incorporated by reference in its entirety as set forth in full.

### BACKGROUND

1. Technical Field

Various embodiments generally relate to a test apparatus, and more particularly, to a test apparatus for a semiconductor apparatus and a test method using the same.

2. Related Art

After packaging, semiconductor apparatuses are tested and then classified into working products and defective products.

When a failure occurs in the packaged semiconductor apparatuses, a failure analysis process is performed on the defective semiconductor apparatuses. The failure analysis process may include the processes of defective cause analysis, defective state reproduction and solution deduction, defective sample collection, decapsulation, and circuit correction and result analysis.

Among the failure analysis processes, the decapsulation process may include a process of determining whether or not a semiconductor apparatus as a device under test (DUT) is affected by the decapsulation. In the decapsulation process, the decapsulated semiconductor apparatus is transferred to test equipment, and the test equipment performs testing on the decapsulated semiconductor apparatus.

The time, effort, cost, and the like required for the test of the semiconductor apparatus are directly related to the production efficiency of the semiconductor apparatus. Therefore, more effective test methods are needed.

### SUMMARY

According to an embodiment, there may be provided a portable test apparatus. The portable test apparatus may include a socket board configured to allow mounting of a semiconductor apparatus decapsulated for package testing. The portable test apparatus may include a test logic board electrically coupled to the socket board, the test logic board configured to perform a test on the semiconductor apparatus and for analyzing a test result. The test logic board may receive power through the socket board. The test logic board may be configured for receiving a command from outside the test apparatus, generating and analyzing a test pattern, and outputting the test result.

According to an embodiment, there may be provided a method of testing a semiconductor apparatus using a portable test apparatus. The portable test apparatus may include a socket board configured to allow mounting of a semiconductor apparatus decapsulated for package testing. The portable test apparatus may include a test logic board electrically coupled to the socket board, and configured to perform testing with the semiconductor apparatus and analyze a test result. The method may include determining whether or not a command external to the test logic board has been received by the test logic board while the test logic board is in a standby state. The method may include performing tests with the semiconductor apparatus according to a test mode corresponding to the command in response to receiving the command. The method may include analyzing a test performance result and outputting an analyzed result.

### BRIEF DESCRIPTION OF THE DRAWINGS

FIG. 1 is a configuration diagram illustrating a representation of an example of a test apparatus according to an embodiment.

FIG. 2 is a configuration diagram illustrating a representation of an example of a test logic board according to an embodiment.

FIG. 3 is a configuration diagram illustrating a representation of an example of an input circuit unit according to an embodiment.

FIG. 4 is a configuration diagram illustrating a representation of an example of an output circuit unit according to an embodiment.

FIG. 5 is a configuration diagram illustrating a representation of an example of a socket board according to an embodiment.

FIG. 6 is a flowchart illustrating a representation of an example of a test method according to an embodiment.

FIG. 7 is a flowchart illustrating a representation of an example of a test result output method according to an embodiment.

### DETAILED DESCRIPTION

Various examples of embodiments will be described below with reference to the accompanying drawings. Various examples of the embodiments are described herein with reference to cross-sectional illustrations that are schematic illustrations of the various examples of the embodiments (and intermediate structures). As such, variations from the shapes of the illustrations as a result, for example, of manufacturing techniques and/or tolerances, are to be expected. Thus, embodiments should not be construed as limited to the particular shapes illustrated herein but may include deviations in shapes that result, for example, from manufacturing. In the drawings, lengths and sizes of layers and regions may be exaggerated for clarity. Like reference numerals in the drawings denote like elements. It is also to be understood that when a layer is referred to as being “on” another layer or substrate, it can be directly on the other or substrate, or intervening layers may also be present. It is also noted that in this specification, “connected/coupled” refers to one component not only directly coupling another component but also indirectly coupling another component through an intermediate component. In addition, a singular form may include a plural form, and vice versa as long as it is not specifically mentioned.

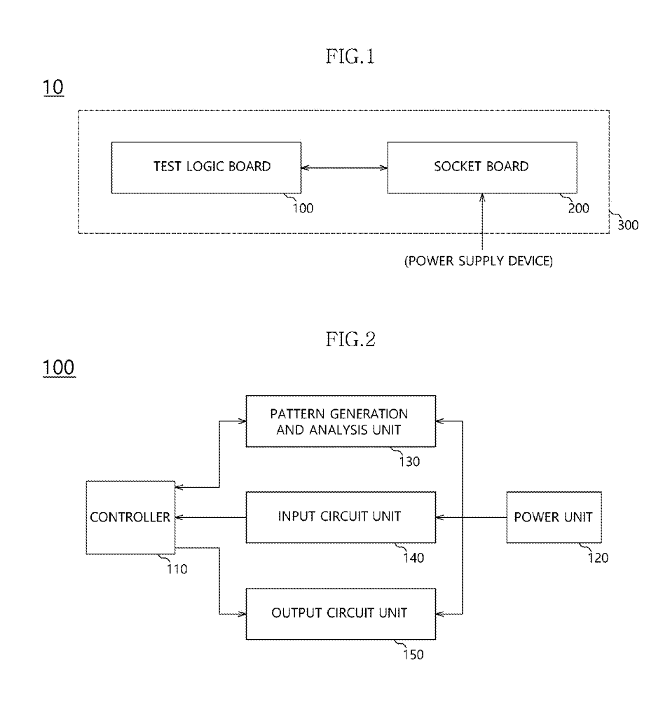

FIG. 1 is a configuration diagram illustrating a representation of an example of a test apparatus according to an embodiment.

Referring to FIG. 1, a test apparatus 10 for a semiconductor apparatus according to an embodiment may be portable, and the test apparatus 10 may include a test logic board 100 and a socket board 200.

For example, the test logic board 100 may receive power through the socket board 200. The test logic board 100 may receive a user command, generate and analyze a test pattern for a semiconductor apparatus as a device under test (DUT) mounted on the socket board 200, and output a test result. In an embodiment, the semiconductor apparatus as the DUT may be a semiconductor apparatus decapsulated in a package test level.

The test logic board 100 may receive the user command, for example, through a user manipulator. The user manipulator may be configured in a button type.

In an embodiment, the test logic board 100 may be connected to an external apparatus such as a personal computer (PC) in a wired manner, and the test logic board 100 may receive the user command input to the PC.

In an embodiment, the test logic board 100 may be connected to an external apparatus such as a portable terminal (for example, a portable communication terminal) in a wireless manner, and the test logic board 100 may receive the user command input to the portable terminal.

The test logic board 100 may include an output circuit unit configured to output the test result. The output circuit unit may be a device may be configured for outputting a signal corresponding to the test result as a lighting signal. In an embodiment, the output circuit unit may include a light emitting diode (LED) module. The test result of the test logic board 100 may also be output to the external apparatus connected thereto in a wired or wireless manner.

In an embodiment, the test logic board 100 may be connected to the external apparatus such as a PC or a portable terminal through a universal serial bus (USB) cable. The USB cable may perform signal exchange between the test logic board 100 and the external apparatus.

For example, the USB cable may convert a USB signal to a universal synchronous/asynchronous receiver transmitter (USART) signal or covert the USART signal to the USB signal.

In an embodiment, the test logic board 100 may be connected to the external apparatus such as a PC or a portable terminal through a wireless communication network. For example, the test logic board 100 may include a wireless communication module such as a Bluetooth module, and the Bluetooth module may perform signal exchange between the test logic board 100 and the external apparatus.

The test logic board 100 may be connected to an external apparatus. The external apparatus may support the same communication standard as a communication standard supported in the test logic board 100.

The socket board 200 may supply power to the test logic board 100 by converting a level of the power provided from a power supply device. The socket board 200 may also generate an internal voltage for a semiconductor apparatus from the power supplied from the power supply device.

The socket board 200 may include at least one socket for mounting the semiconductor apparatus on. The semiconductor apparatus mounted on the socket may be operated by receiving the internal voltage from the socket. The semiconductor apparatus may generate an output signal in response to a test signal provided from the test logic board 100, and the socket board 200 may transmit the output signal of the semiconductor apparatus to the test logic board 100.

In an embodiment, the socket board 200 may be configured to convert levels of signals transmitted and received between the test logic board 100 and the semiconductor apparatus.

The power supply device supplying the power to the socket board 200 may be, for example, a PC, a portable terminal, a portable battery, an auxiliary battery of the portable terminal, and the like, but the power supply device is not limited thereto.

In an embodiment, the test logic board 100 and the socket board 200 may be manufactured on individual boards, and may be electrically coupled, for example, through a cable.

In an embodiment, the test logic board 100 and the socket board 200 may be manufactured on a single board as a test board 300. In these embodiments, the test logic board 100 and the socket board 200 may be electrically coupled, for example, through a wire.

When the semiconductor apparatus decapsulated in the package test level is tested, the test apparatus 10 according to an embodiment may be directly used in the field. That is, the decapsulated semiconductor apparatus may be directly and immediately tested in the test field without the movement of the decapsulated semiconductor apparatus to a remote place in which high-priced large test equipment is located.

The test apparatus 10 may be manufactured to have a portable size and weight. For example, the size of the test apparatus 10 may have (10˜20)cm in width, (10˜20)cm in length, (5˜15)cm in height, and the weight may have (100˜200)g.

A PC, a portable terminal, or an auxiliary battery of the portable terminal may be used as a power supply source of the test apparatus 10, and thus the test apparatus 10 may have a good portability and reduce the time required for testing of the semiconductor apparatus.

The user command may be input through a manipulator provided in the test apparatus 10, and the test apparatus 100 may immediately notify the user of the test result through a lighting module such as a LED module. Therefore, test efficiency may be maximized.

FIG. 2 is a configuration diagram illustrating a representation of an example of a test logic board according to an embodiment.

Referring to FIG. 2, the test logic board 100 may include a controller 110, a power unit 120, and a pattern generation and analysis unit 130. The test logic board 100 may include an input circuit unit 140 and an output circuit unit 150.

The controller 100 may control an overall operation of the test logic board 100.

The power unit 120 may supply power provided from the outside to the components of the test logic unit 100. In an embodiment, the power unit 120 may be configured to receive the level-converted power from the socket board 200.

The pattern generation and analysis unit 130 may generate a test pattern based on the kinds of semiconductor apparatus as the DUT and test, and provide the generated test pattern to the socket board 200. The pattern generation and analysis unit 130 may receive a test output signal from the socket board 200 and analyze the test result.

In an embodiment, the pattern generation and analysis unit 130 may be implemented with a field programmable gate array (FPGA) logic, or an application-specific integrated circuit (ASIC) logic, but the pattern generation and analysis unit 130 is not limited thereto.

The input circuit unit 140 may receive the user command and provide the received user command to the controller 110. The input circuit unit 140 may receive the user command through the manipulator or may receive the user command provided from the external apparatus such as a PC or a portable terminal.

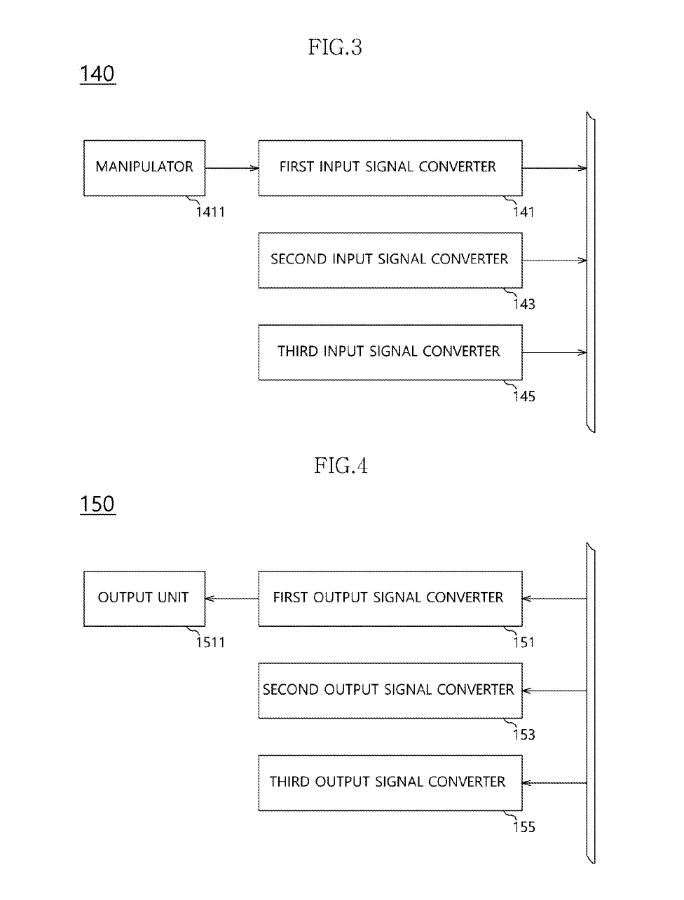

FIG. 3 is a configuration diagram illustrating a representation of an example of an input circuit unit according to an embodiment.

Referring to FIG. 3, the input circuit unit 140 may include at least one input signal converter 141, 143, and 145.

A first input signal converter 141 may be configured to receive a command received through a manipulator 1411, decode the received command, and provide the decoded command to the controller 110 (i.e., see FIG. 2). In an embodiment, the manipulator 1411 may be implemented in a button type, and the manipulator 1411 may include a reset button, an operation mode selection button, and the like. Wherein, the reset button is configured to reset the test logic board, and the operation mode selection button is configured to select one of a plurality of test modes.

A second input signal converter 143 may receive a command provided from an external apparatus connected to the test logic board 100 in a wired manner, convert the received command based on the communication standard supported in the test logic board 100, and provide the converted command to the controller 110 (i.e., see FIG. 2).

In an embodiment, the test logic board 100 may be connected to an external apparatus through a USB cable, and the second input signal converter 143 may convert a USB signal to a USART signal so that the signal provided from the external apparatus is capable of being recognized in the test logic board 100.

A third input signal converter 145 may receive a command provided from an external apparatus connected to the test logic board 100 in a wireless manner, covert the received command based on the communication standard supported in the test logic board 100, and provide the converted command to the controller 110 (i.e., see FIG. 2).

In an embodiment, the test logic board 100 may be connected to an external apparatus through a wireless communication network, and the third input signal converter 145 may convert a signal provided from the external apparatus through a wireless communication module to a USART signal so that the signal provided from the external apparatus is capable of being recognized in the test logic board 100. The wireless communication module may be a Bluetooth module, but the wireless communication module is not limited thereto. The wireless communication module may include a wireless communication module corresponding to a wireless communication module provided in the external apparatus wirelessly connected to the test logic board 100, such as, for example but not limited to, a WIFI module or a Zigbee module.

Referring to FIG. 2, the output circuit unit 150 may be configured to receive the test analysis result from the controller 110, and output the received test analysis result. The output circuit unit 150 may output the test analysis result through a lighting module or output the test analysis result to an external apparatus such as a PC or a portable terminal. In an embodiment, the output circuit unit 150 may output the test analysis result through the lighting module and simultaneously output or substantially simultaneously output the test analysis result to the external apparatus.

FIG. 4 is a configuration diagram illustrating a representation of an example of an output circuit unit according to an embodiment.

Referring to FIG. 4, the output circuit unit 150 may include at least one output signal converter 151, 153, and 155.

A first output signal converter 151 may be configured to output the test analysis result provided from the controller 110 through an output unit 1511. For example, the out unit 1511 may be a lighting module using a LED. The output unit 1511 may be configured to drive a lighting device corresponding to a corresponding semiconductor apparatus when the semiconductor apparatus is a good product (i.e., functioning properly or as expected) and drive a corresponding lighting device corresponding to a corresponding semiconductor apparatus when the semiconductor apparatus is a defective product (i.e., not functioning properly or not as expected), according to the test analysis result. Accordingly, the user may intuitively determine the test analysis result.

A second output signal converter 153 may convert a signal, which is to be transmitted to an external apparatus coupled to the test logic board 100 in a wired manner, based on a communication standard supported in the external apparatus.

In an embodiment, the test logic board 100 may be connected to an external apparatus through a USB cable, and the second output signal converter 153 may convert a USART signal to a USB signal so that the signal provided from the test logic board 100 is capable of being recognized in the external apparatus.

A third output signal converter 155 may convert a signal, which is to be transmitted to an external apparatus coupled to the test logic board 100 in a wireless manner, based on a communication standard supported in the external apparatus.

In an embodiment, the test logic board 100 may be connected to an external apparatus through a wireless communication network, and the third output signal converter 155 may convert a USART signal provided from the controller 110 to a radio frequency (RF) signal so that the signal provided from the test logic board 100 is capable of being recognized in the external apparatus. The wireless communication module may be a Bluetooth module, but the wireless communication module is not limited thereto. The wireless communication module may include a wireless communication module corresponding to a wireless communication module provided in the external apparatus wirelessly connected to the test logic board 100, such as, for example but not limited to, a WIFI module or a Zigbee module.

FIGS. 3 and 4 illustrate that the second input signal converter 143 and the second output signal converter 153 are separately configured from each other, However, the second signal converter 143 and the second output signal converter 153 may be configured of a single interface device which may enable signal exchange between the test logic board 100 and the external apparatus through signal conversion between the USB signal and the USART signal.

Similarly, the third input signal converter 145 and the third output signal converter 155 may be configured of a single interface device which may enable RF signal exchange between the test logic board 100 and the external apparatus or apparatuses.

FIG. 5 is a configuration diagram illustrating a representation of an example of a socket board according to an embodiment.

Referring to FIG. 5, the socket board 200 may be configured to include a power unit 210, an internal voltage generator 220, and a socket 240.

The power unit 210 may convert power provided from an external apparatus to power having a level which may be usable in the test apparatus 10. The power level-converted in the power unit 210 may be provided to the test logic board 100 (i.e., see FIG. 1).

The test logic board 100 may be, for example, a high-voltage (for example, 3.3V)-based board or a low-voltage (for example, 1.5 V)-based board, and the power unit 210 may convert the power provided from the external apparatus to power having a level suitable for power used in the test logic board 100.

The internal voltage generator 220 may generate an internal voltage for a semiconductor apparatus mounted on the socket 240 from the power level-converted in the power unit 210, and provide the generated internal voltage to the socket 240. The internal voltage for the semiconductor apparatus may be determined according to the kind of the semiconductor apparatus as the DUT.

The semiconductor apparatus decapsulated in the package test level may be mounted on the socket 240. The socket board 200 may include at least one socket 240. A given number of sockets 240 (for example, 10 or less sockets), in which portability of the test apparatus 10 is not hindered, may be installed in the socket board 20.

The socket board 200 may further include a level converter 230.

A test-related signal TS between the test logic board 100 and the semiconductor apparatus mounted on the socket 240 may be directly transmitted and received. The test-related signal TS between the test logic board 100 and the semiconductor apparatus mounted on the socket 240 may be transmitted and received via the level converter 230.

When a potential level of the test-related signal TS (for example, data, a command, and a strobe signal) generated from the test logic board 100 is different from a voltage level of the internal voltage of the semiconductor apparatus mounted on the socket 240, the level converter 230 may perform a function to convert potential levels of signals transmitted and received between the test logic board 100 and the socket 240.

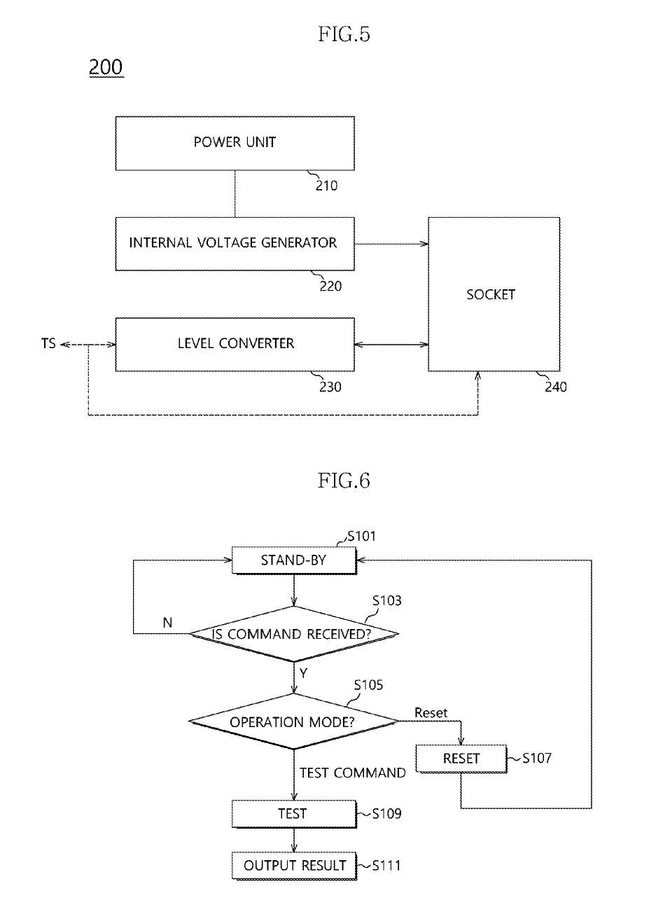

FIG. 6 is a flowchart illustrating a representation of an example of a test method according to an embodiment.

Referring to FIG. 6, first, power supplied through an external apparatus may be level-converted, for example, in the power unit 210 of the socket board 200 (i.e., see FIG. 5). The level-converted power may be applied to the test logic board 100 (i.e., see FIG. 1), and the test apparatus 10 may be in a stand-by state (S101).

The controller 110 of the test logic board 100 may be determined whether or not a user command is received in the stand-by state (S103). When the user command is received in the stand-by state (S103-Y), the controller 110 of the test logic board 100 may determine an operation mode by analyzing the received user command (S105).

In an embodiment, the user command may be input to the test logic board 100 through the manipulator 1411 or an external apparatus such as a PC or a portable terminal (i.e., see FIG. 3).

When it is determined that the user command is a reset command as the operation mode determination result in operation S105, the controller 110 may reset the test logic board 100 (S107), and the process may transition to the stand-by state (S101).

When it is determined that the user command is a test command as the operation mode determination result in operation S105, the controller 110 may perform a test operation (S109), and the controller 110 may analyze the test result and output the analysis result (S111).

The test mode may be, for example but not limited to, any one of an open-circuit/short-circuit test mode, a function test mode, a die identification (ID) output mode, a customer request test mode, and an oscillation signal measurement mode for temperature-compensated self-refresh (TCSR).

The open-circuit/short-circuit test mode may be a mode testing for a short-circuit and an open-circuit of a corresponding semiconductor apparatus. For the open-circuit/short-circuit test, the test logic board 100 may enable a reset signal and a clock signal, transmit the enabled reset signal and clock signal to the semiconductor apparatus mounted on the socket 240 of the socket board 200, and match ZQ impedance of the semiconductor apparatus. The test logic board 100 may set DQ strength, a reference voltage, and DQ impedance through a mode register write (MRW) operation. Then, the test logic board 100 may repeatedly perform an operation of generating DQ expected data, receiving DQ test data from the semiconductor apparatus, comparing the DQ test data with the DQ expected data, and determining whether the semiconductor apparatus is passed or failed a given number of times. The MRW operation and the comparison/determination operation may be repeatedly performed while changing MRW data and the DQ impedance value. Whenever the open-circuit/short-circuit test is repeated, the pattern generation and analysis unit 130 of the test logic board 100 may count a number of times being passed/failed, and the output operation (S111) may be performed according to the counting result.

The function test mode may be a write/read test for the semiconductor apparatus. For the function test mode, the test logic board 100 may enable the reset signal and the clock signal, transmit the enabled reset signal and clock signal to the semiconductor apparatus mounted on the socket 240 of the socket board 200, and match ZQ impedance of the semiconductor apparatus. The test logic board 100 may set DQ strength, a reference voltage, and DQ impedance through a MRW operation. Then, the test logic board 100 may repeatedly perform a write and read operation for a specific test pattern a preset number of times while changing an address of the semiconductor apparatus. The test logic board 100 may change the test pattern and repeatedly perform the write and read operation for the changed test pattern a preset number of times while changing the address of the semiconductor apparatus. Whenever the function test is repeated, the pattern generation and analysis unit 130 of the test logic board 100 may count a number of times being passed/failed according to comparison of a read result after write, and the output operation (S111) may be performed according to the counting result.

For the die ID output operation, the test logic board 100 may enable the reset signal and the clock signal, transmit the enabled reset signal and clock signal to the semiconductor apparatus mounted on the socket 240 of the socket board 200, and match ZQ impedance of the semiconductor apparatus. The test logic board 100 may set DQ strength, a reference voltage, and DQ impedance through a MRW operation. Then, the test logic board 100 may receive the die ID from the semiconductor apparatus and may perform the output operation (S111).

The customer request test mode may be a mode for testing the semiconductor apparatus according to a test pattern requested by a customer. For the customer request test mode, the test logic board 100 may enable the reset signal and the clock signal, transmit the enabled reset signal and clock signal to the semiconductor apparatus mounted on the socket 240 of the socket board 200, and match ZQ impedance of the semiconductor apparatus. The test logic board 100 may set DQ strength, a reference voltage, and DQ impedance through a MRW operation. Then, the test logic board 100 may provide the test pattern coded according to the customer request to the semiconductor apparatus, and may perform the output operation (S111) through comparison and analysis of data received from the semiconductor apparatus.

The TCSR oscillation signal measurement mode may be a mode which determines whether or not an oscillation signal is output at a preset interval. For the TCSR oscillation signal measurement mode, the test logic board 100 may enable the reset signal and the clock signal, transmit the enabled reset signal and clock signal to the semiconductor apparatus mounted on the socket 240 of the socket board 200, and match ZQ impedance of the semiconductor apparatus. The test logic board 100 may set DQ strength, a reference voltage, and DQ impedance through a MRW operation. Then, the test logic board 100 may count a number of strobe signals having a low level output from the semiconductor apparatus by generating a strobe signal every preset interval and providing the generated strobe signal to the semiconductor apparatus, and the test logic board 100 may perform the output operation (S111) according to a counting result.

The open-circuit/short-circuit test method, the function test method, the die ID output method, the customer request test method, and the oscillation signal measurement method for TCSR are not limited thereto, and the methods may be variously changed.

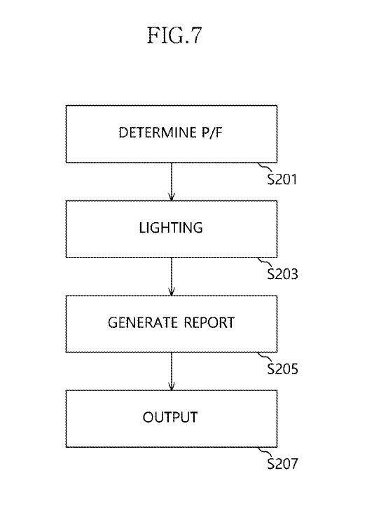

The output operation (S111) may be performed through the output unit 1511 provided in the test logic board 100 or an external apparatus which is electrically coupled to the test logic board 100, such as a PC or a portable terminal. FIG. 7 illustrates a representation of an example of a test result output method according to an embodiment.

Referring to FIG. 7, the pattern generation and analysis unit 130 of the test logic board 100 may determine whether or not a semiconductor apparatus is passed (P) or failed (F) according to the test result in operation S109 (S201).

The controller 110 may drive the output unit 1511 according to the determination result in operation S201 (S203). The output unit 1511 may be, for example, a lighting module using a LED. The output unit 1511 may drive a lighting device corresponding to a corresponding semiconductor apparatus when the semiconductor apparatus is a good product according to the test analysis result, and the output unit 1511 may drive a lighting device corresponding to a corresponding semiconductor apparatus when the semiconductor apparatus is a defective product according to the test analysis result. Therefore, the user may intuitively determine the test analysis result.

The pattern generation and analysis unit 130 may generate a report based on the test result (S205), and output the generated report to an external apparatus (S207).

Therefore, the user may immediately determine the test result through the output unit 1511 or through an output device of an external apparatus, for example, a display.

The above embodiments of the are illustrative and not limitative. Various alternatives and equivalents are possible. The disclosure is not limited by the embodiments described herein. Nor are the embodiments limited to any specific type of semiconductor device. Other additions, subtractions, or modifications are obvious in view of the present disclosure and are intended to fall within the scope of the appended claims.

What is claimed is:

1. A portable test apparatus comprising:
a socket board configured to allow mounting of a semiconductor apparatus decapsulated for package testing; and
a test logic board electrically coupled to the socket board, the test logic board configured to perform a test on the semiconductor apparatus and for analyzing a test result,
wherein the test logic board and the socket board are configured to portable.

2. The portable test apparatus of claim 1, wherein the test logic board is configured to include:
an input circuit unit configured to receive a command externally from the test apparatus;
a pattern generation and analysis unit configured to provide a test pattern to the socket board, receive test data from the socket board, and generate a test analysis result in response to the command externally received from the test apparatus; and
an output circuit unit configured to output the test analysis result externally from the test logic board.

3. The portable test apparatus of claim 1, wherein the test logic board further includes:
a manipulator configured to receive a command externally received from the test apparatus.

4. The portable test apparatus of claim 3, wherein the manipulator includes a reset button and an operation mode selection button.

5. The portable test apparatus of claim 1, wherein the test logic board includes the output circuit unit configured to output a test analysis result of the semiconductor apparatus.

6. The portable test apparatus of claim 5, wherein the output circuit unit includes an output unit configured to drive a lighting device.

7. The portable test apparatus of claim 1, wherein the test logic board and the socket board are located on individual boards apart from each other, and are configured to electrically connect with each other.

8. The portable test apparatus of claim 1, wherein the test logic board and the socket board are located on a single board, and are electrically connect with each other.

9. The portable test apparatus of claim 1, wherein the test logic board is configured for exchanging signals with apparatuses external to the portable test apparatus.

10. The portable test apparatus of claim 9, wherein the test logic board includes a single interface device configured to perform signal exchange with the apparatuses external to the portable test apparatus through coupling with the external apparatuses in a wired manner.

11. The portable test apparatus of claim 9, wherein the test logic board includes a single interface device configured to perform signal exchange with the apparatuses external to the portable test apparatus through communicating with the external apparatuses wirelessly.

12. The portable test apparatus of claim 1, wherein the socket board is configured to include:
a power unit configured to convert a power level of power provided from an external apparatus;
an internal voltage generator configured to generate an internal voltage for the semiconductor apparatus from the power output from the power unit; and
at least one socket mounted to the semiconductor apparatus.

13. The portable test apparatus of claim 11, wherein the socket board further includes:
a level converter configured to convert potential levels of signals transmitted and received between the test logic board and the semiconductor apparatus.

14. The portable test apparatus of claim 1, wherein the test logic board includes a pattern generation and analysis unit configured to implement a field programmable gate array (FPGA) logic.

15. The portable test apparatus of claim 1, wherein the test logic board includes a pattern generation and analysis unit configured to implement an application-specific integrated circuit (ASIC) logic.

16. A method of testing a semiconductor apparatus using a portable test apparatus including:
a socket board configured to allow mounting of a semiconductor apparatus decapsulated for package testing; and
a test logic board electrically coupled to the socket board, and configured to perform testing with the semiconductor apparatus and analyze a test result, the method comprising:
determining whether or not a command external to the test logic board has been received by the test logic board while the test logic board is in a standby state;
performing tests with the semiconductor apparatus according to a test mode corresponding to the command in response to receiving the command;
analyzing a test performance result; and
outputting an analyzed result.

17. The method of claim 16, wherein the command is received through a manipulator included in the test logic board.

18. The method of claim 17, wherein the manipulator is includes a reset button and an operation mode selection button.

19. The method of claim 16, wherein the command is received through an external apparatus connected to the test logic board in a wired manner.

20. The method of claim 16, wherein the user command is received through an external apparatus wirelessly communicatively coupled with the test logic board.

21. The method of claim 16, wherein the test result is output through an output circuit unit provided in the test logic board.

22. The method of claim 21, wherein the output circuit unit includes an output unit, the output unit including a lighting module.

23. The method of claim 16, wherein the test result is output through an external apparatus connected to the test logic board in a wired manner.

24. The method of claim 16, wherein the test result is output to an external apparatus wirelessly communicatively coupled with the test logic board.
